(19) United States
(12) Patent Application Publication
(10) Pub. No.: US 2024/0341118 A1
(43) Pub. Date: Oct. 10, 2024

(54) INTEGRATED OPTOELECTRONIC DEVICES FOR LIGHTING AND DISPLAY APPLICATIONS

(71) Applicant: 10644137 CANADA INC., Calgary (CA)

(72) Inventors: Afshin Shahalizad Namin, Calgary (CA); Hamid Pahlevaninezhad, Calgary (CA); Majid Pahlevaninezhad, Calgary (CA); Sam Scherwitz, Calgary (CA)

(73) Assignee: 10644137 CANADA INC., Calgary, AB (CA)

(21) Appl. No.: 18/578,916

(22) PCT Filed: Jul. 12, 2021
(86) PCT No.: PCT/CA2021/050957

§ 371 Date: Jan. 12, 2024

(51) Int. Cl. H10K 50/856; B82Y 20/00; B82Y 40/00; H10K 71/13; H10K 77/10; H10K 102/00

(52) U.S. Cl. CPC H10K 50/856; B82Y 20/00; B82Y 40/00; H10K 71/13; H10K 77/111; H10K 2102/311; H10K 2102/331

(57) ABSTRACT

Technique for large-scale manufacturing of high-efficiency light-emitting apparatuses for solid-state lighting and display applications are disclosed. The light-emission profiles of the light-emitting apparatuses may be modified through the incorporation of metasurfaces thereinto. The devices may be light-emitting diodes (LEDs), quantum-dot light-emitting diodes (QLEDs), organic light-emitting diodes (OLEDs), and passive-matrix and active-matrix OLED and QLED displays. The integrated metasurfaces are two-dimensional sub-wavelength-spaced nanostructures that enable efficient light extraction from the devices and modification of their emission profiles for desired applications. The light-emitting apparatuses may be fabricated using sheet-to-sheet, roll-to-sheet, and roll-to-roll nanoimprint lithography.

### FIELD OF THE DISCLOSURE

This invention relates to the category of optoelectronic devices. More specifically, the present disclosure relates to fabricating large-area, flexible, roll-to-roll printed quantum-dot light-emitting diodes (QLEDs), organic light-emitting diodes (OLEDs) for solid-state lighting applications with enhanced efficiency and modified emission profile through incorporating metasurfaces. It also relates to the display technology and specifically fabrication of large-area, flexible, sheet-to-sheet, and roll-to-roll printed passive matrix displays.

### BACKGROUND

Semiconducting inorganic colloidal core-shell quantum-dots (QDs) have attracted a tremendous amount of interest, due to their unique optical and electrical properties in quantum-dot light-emitting diodes (QLEDs) and other optical systems, making them suitable, for example, in optoelectronic and biological applications (see References [1] to [3]). This interest mainly arises from the fact that the emission from quantum-dots (QDs) is extremely narrow, which is highly desirable in full-color displays and applications where very narrowband spectral emission is desired (for example, in biological systems) (see References [4] and [5]). Especially, this aspect makes QLEDs superior and indeed irreplaceable to their main high-efficiency opponents (such as organic light-emitting diodes (OLEDs)) which typically exhibit a much broader spectral emission. Furthermore, thanks to their high efficiency, durability, and possibility for making roll-to-roll, large-area devices. QLEDs may be as red, green, blue, and white light sources for solid-state lighting applications.

The emitters in OLEDs are typically conjugated polymers or small-molecule semiconductors. Similar to QLEDs, these devices have a variety of applications in, for instance, portable electronic devices such as smartphones, TVs, biomedical systems, and solid-state lighting devices (see References [6] to [9]). Even though OLED displays and OLED lighting systems have been commercialized, large-area, wearable, and flexible OLED devices still require more technological advancements (see References to [13]). Similarly, flexible QLED lighting and display systems are still facing some technological challenges for commercialization (see References [14] and [15]). For this reason, taking full advantage from sophisticated material developments and device engineering to make these devices as efficient and durable as possible on flexible substrates is of paramount importance.

FIG. 1 displays the structure of a conventional QLED device 10 fabricated on a rigid substrate 12. The device structure comprises a stack of organic and inorganic semiconductors sandwiched between a transparent indium-tin-oxide (ITO) anode 14 and a metallic cathode 24 (usually silver (Ag) or aluminum (Al)). The device may be bottom-emitting (wherein the substrate 12 is a transparent substrate such as glass), top-emitting (wherein the cathode 24 is transparent), or fully transparent (wherein both the substrate 12 and the cathode 24 are transparent). Upon applying a suitable forward bias using a power supply 26, the device emits light through the transparent electrode.

As shown in FIG. 1, the stack of organic and inorganic semiconductors includes, from the anode 14 to the cathode 24, a hole injection layer (HIL) 16, a hole transporting layer/electron blocking layer (HTL/EBL) 18, an emissive layer (EML) 20, and an electron injection layer (EIL)/hole blocking layer (HBL) 22. In operation, holes are injected from the anode 14 and transported through the HIL 16 and HTL/EBL 18 into the EML 20. Electrons are injected from the cathode 24 and transported through the EIL/HBL 22 into the EML 20. Then, electrons and holes form electron-hole pairs (called “excitons”) in the EML 20 and the device 10 emits light upon radiative electron-hole recombination. Excitons may also undergo non-radiative processes (i.e., heat) which leads to excitonic energy losses.

In the conventional QLED device 10, the HTL/EBL 18 and EIL 22 are necessary to confine electrons and holes injected from the corresponding electrodes 14 and 24 into the EML 20 in order to improve the charge balance and subsequently maximize the device efficiency and lifetime as well to minimize the turn-on voltage. The HIL 16 is typically poly(3,4-ethylenedioxythiophene) polystyrene sulfonate (PEDOT:PSS) or other suitable material. The HTL/EBL 18 may be poly(9)-vinlycarbazole) (PVK), poly (N,N′,-bis(4-butylphenyl)-N,N′-bisphenylbenzidine) (poly-TPD), poly [(9,9-dioctylfluorenyl-2,7-diyl)-co-(4,4′-(N-(p-butylphenyl))diphenylamine)] (TFB), or other suitable material. These materials are commercially available from various suppliers.

Unlike OLEDs that are hole-dominant devices. QLEDs are electron-dominant devices due to the extremely small energy barrier for electron injection from the cathode into the EIL 22 and subsequently to the EML 20. Thus, conventional QLEDs 10 often use ZnO nanoparticles as the EIL 22 because of its high electron mobility. However, since there is a large energy barrier for hole injection from the HIL 16 into the EML 20, insertion of the HTL/EBL 18 provides a step-wise hole injection pathway. Combination of TFB/PVK double-HTL 18 has been found to be very 30) effective for better hole injection into the EML 20 (see Reference [16]).

Inverted QLEDs can also be fabricated. As shown in FIG. 2, an inverted QLED 10 has a structure similar to that shown in FIG. 1 except that the substrate 12 is coupled to the cathode 24 rather than the anode 14. The inverted QLED 10 may be bottom-emitting, top-emitting, or fully-transparent, depending on whether the anode 14 and cathode 24 are transparent or opaque.

The conventional QLED 10 shown in FIGS. 1 and 2 typically comprises a single layer of cadmium (Cd)-based (see References [17] to [20]) or Cd-free colloidal core/shell QDs (see References [21] to [24]) EML 20 with a thickness of 15-90 nanometers (nm).

Applicant's PCT Patent Publication No. WO 2019/071362 A1, entitled “Multiple-Layer Quantum-Dot LED and Method of Fabricating Same”, published on Oct. 18, 2019, the content of which is incorporated herein by reference in its entirety, discloses a highly efficient QLED structure 10′ wherein the EML 20 thereof comprises one or more quantum-barriers (QBs) sublayers 34 for providing a better exciton confinement.

As shown in FIG. 3, the EML 20 of the QLED 10′ disclosed in WO 2019/071362 A1 comprises a plurality of thin Cadmium Selenide/Zinc Sulfide (CdSe/ZnS) core/shell QD sublayers 32 (for example, three CdSe/ZnS QD sublayers 32) and one or more ultrathin (insulating) poly (methyl metacrylate) (PMMA) QB sublayers 34 (for example, two PMMA QB sublayers 34) which effectively confine the excitons into the CdSe/ZnS QD sublayers 32. In the QLED 10′ disclosed in WO 2019/071362 A1. HIL 16, HTL/EBL 18, and EIL 22 comprise PEDOT:PSS. PVK, and ZnO nanoparticles, respectively. Moreover, the cathode 24 of the QLED 10′ may be thermally deposited, and all other layers thereof may be fabricated by the spin coating technique.

A conventional OLED device, such as a solution-processed, bottom-emitting LED device, may have a similar structure as that of the conventional QLED device 10 shown in FIGS. 1 and 2, where the HIL 16. HTL/EBL 18, and EIL/HBL 22 are, for example but not limited to, PEDOT:PSS, PVK, and ZnO nanoparticles, respectively. The EML 20 may be a luminescent conjugated polymer (see References [26] to [28]). The OLED device 10 may also be an OLED where a stack of organic small-molecule semiconductors is thermally deposited as the charge transporting layers 18 and 22 and EML 20. The emitter in the EML 20 may be any fluorescent, phosphorescent, or thermally activated delayed fluorescent (TADF) material doped into a suitable host matrix (see References [29] to [31]).

Optical losses in OLEDs and QLEDs limit the maximum light outcoupling efficiency of these devices to only 20% (see References [32] and [33]). For example, in device 10, more than 50% of the light generated inside the device is lost due to coupling to the surface plasmon polaritons (SPPs) (that is, light reabsorption) at the cathode 24/EIL 22 interface (see References [32] to [34]). On the other hand, since OLEDs and QLEDs can be considered as weak micro-cavities (see References [35] and [36]), the losses associated with the waveguiding effects, which occur due to the differences in the refractive indexes of the adjacent layers, trap the light generated inside the device.

In device 10, for instance, high-reflective index layers (with a refractive index n_{anode} of about 2 and a refractive index n_{organic inorganic} of about 1.7-1.9) are sandwiched between a glass substrate 12 with the low refractive index of n_{glass} of about 1.5 and a reflective metallic cathode 24. As shown in FIG. 4, when the light 42 generated in the EML 20 passes through the glass substrate 12 at an angle (θ) 44 greater than the critical angle (θ_{c}) 46, the light 42 is totally reflected back in the glass substrate 12 (referred to as “total internal reflection” (TIR): see the light 42″) at the interface between the glass 12 and air (with a refractive index nₐᵢᵣ of about 1). A similar process occurs at the interfaces between the organic and inorganic layers. Therefore, a large portion of the generated light is trapped inside the device as “waveguide modes” in the layers and in the substrate (called the “substrate modes”).

The light outcoupling efficiency may be enhanced by incorporating dielectric or metallic SPP diffraction gratings into OLEDs and QLEDs (see References [37] to [39]). Furthermore. FIG. 5 shows an array of high-index micro-lenses 52 fabricated on the backside of an ITO-coated glass substrate 12, which are commonly used for enhancing the light outcoupling efficiency of small-area bottom-emitting devices (see References [40] and [41]). However, diffraction gratings and micro-lenses have not been widely applied to large-area, ultrathin plastic optoelectronic devices (for example, displays) due to the increased form factor and difficulty of integration. On the other hand, most of these traditional components do not offer any more desired optical features, other than enhancing the light extraction from LED devices.

Metasurfaces are also known. As shown in FIG. 6, a metasurface 60) is an ultra-thin optical component comprising a two-dimensional (2D) array of nanostructures 62 (also called metalenses; typically fabricated from high-index materials) on a rigid or flexible substrate 12. Electron-beam, deep-ultraviolet and nanoimprint lithographic techniques are commonly used for the fabrication of metasurfaces (see References [42] to [44]). By changing the geometry and distribution of these subwavelength-spaced nanostructures, metasurfaces can impart predefined phase into light to allow control over basic properties of light such as its phase, amplitude, and polarization (see References [42] to [44]).

Highly efficient small-area QLEDs on glass substrates have been realized in lab scale (see References [45] to [49]). However, from the commercialization perspective, large-area, flexible QLED panels for solid-state lighting and display applications are still missing. Additionally, much effort has been directed towards the realization of QLED displays by direct electrical excitation, without being limited to only using (optically excited) QD layers as color-filters in liquid crystal (LCD) displays (see References [50] to [52]). On the other hand, from the fabrication point of view: thermal evaporation may not be suitable for making large-area optoelectronic devices because it is technically complex and expensive. For this reason, roll-to-roll solution-processing (or printing) can utilized as the best low-cost thin film processing technique for mass-production of electronic devices including OLED and QLED panels of limited width (see References [53] and [54] for roll-to-roll fabricated OLEDs). Devices with a few meters of width and several hundred meters of length can be fabricated and then cut into small slices after the fabrication process is complete. However, hitherto, roll-to-roll solution-processing has not yet been used for the fabrication of QLED panels with large width and length.

For example, FIG. 7 shows a simplified prior-art roll-to-roll processing setup. A more advanced roll-to-roll printing setup for making electronic devices has been disclosed, for example, in U.S. Pat. No. 8,689,687 B2 issued on Apr. 8, 2014, entitled “Method and Apparatus for Manufacturing Electronic Device using Roll-to-Roll Rotary Pressing Process” [55].

As shown in FIG. 7, a flexible plastic (of any type) or a flexible glass substrate 72 is moved from the unwinding roller 74 toward the wind-up roller 76, while simultaneously using the slot-die head 78 to print the solution 80 onto the substrate 72. The device 82 is fabricated with sequential printing and baking of organic and inorganic materials by controlling the printing web speed, solution flow rate, printing temperature etc. (see Reference [60]). In most cases, it is also required to coat a printable encapsulation material to protect the device 82 against extrinsic degradations that are caused primarily by air, moisture, and exposure to the environment UV light. However, highly-efficient, durable, fully-solution-processed, large-area, industry-scale QLEDs have not been realized to date.

In prior art, rolls of ITO-coated polyethylene terephthalate (PET), polyethylene naphthalate (PEN), polycarbonate (PC), and polyimide (PI) are widely used as the plastic substrates for making electronic devices in roll-to-roll processes. Additionally, flexible thin glass substrates have recently gained a lot of interest in printing technologies. However, ITO is brittle and has a low sheet conductance on flexible plastic or glass substrates, which therefore dramatically limit their applications in bendable optoelectronic devices.

### SUMMARY

According to one aspect of this disclosure, there is provided a light-emitting component comprising: a plurality of photon generation and transferring layers, the photon generation and transferring layers comprising an emissive layer for generating photons and one or more photon-transferring layers coupled to the emissive layer for transferring photons from the emissive layer for emitting light; and one or more metasurface layers, each metasurface layer comprising a two-dimensional (2D) array of nanostructures, and the one or more metasurface layers comprising one or more first metasurface layers each sandwiched between a neighboring pair of the photon generation and transferring layers for reducing photon reflection at an interface thereof.

In some embodiments, the one or more photon-transferring layers comprise a plurality of photon-transferring layers on opposite sides of the emissive layer.

In some embodiments, the one or more photon-transferring layers are on a first side of the emissive layer; and the one or more metasurface layers further comprise a second metasurface layer on a second side of the emissive layer opposite to the first side thereof for reflecting the photons towards the first side.

In some embodiments, the one or more metasurface layers further comprise a third metasurface layer coupled to an outer side of an outmost layer of the one or more photon-transferring layers for adjusting at least one of a phase, an amplitude, and a polarization of the emitted light.

In some embodiments, the array of nanostructures of the third metasurface layer are determined using a machine-learning method for forming a predefined light pattern on a target plane.

In some embodiments, the machine-learning method is configured for calculating angular coordinates of the emitted light for forming the predefined light pattern on the target plane.

In some embodiments, the emitted light is emitted from a plurality of pixels; and the machine-learning method is configured for using a normalized mean square error (NMSE) as a cost function to be minimized where

$$NMSE = \frac{\sqrt{\frac{{\sum }_{i = 1}^{N} {( I ( {x}_{i} ) - μ )}^{2}}{N}}}{{\sum }_{j = 1}^{N} I ( {x}_{j} )}$$

where μ is a mean value, I (xᵢ) is an intensity for pixel i, and N is a total number of pixels in the image plane.

In some embodiments, the machine-learning method is configured for using a gradient descent (GD) and simulated annealing (SA) method to find a global minimum of NMSE.

In some embodiments, the light-emitting component further comprises a transparent substrate coated with transparent indium-tin-oxide (ITO).

In some embodiments, the light-emitting component further comprises a transparent substrate coated with transparent silver nanowires (Ag NWs) or a hybrid of Ag NWs and carbon nanotubes (hybrid Ag NWs/CNTs).

In some embodiments, the substrate is a flexible substrate such as plastic or thin glass.

In some embodiments, the substrate comprises polyethylene terephthalate (PET), polyethylene naphthalate (poly (ethylene 2,6-naphthalate) or PEN), polycarbonates (PC), or polyimide (PI).

In some embodiments, the photon generation and transferring layers and the one or more metasurface layers are fabricated using spin coating or slot-die coating.

In some embodiments, at least one of the one or more metasurface layers is printed on a neighboring layer thereof.

In some embodiments, the light-emitting component is an inorganic light-emitting diode (LED), an organic light-emitting diode (OLED) with the emissive layer thereof comprising an organic emitter, or a quantum-dot (QD) light-emitting diode (QLED) with the emissive layer thereof comprising one or more QD sublayers.

In some embodiments, the light-emitting component is a passive-matrix OLED or QLED, or an active-matrix OLED or QLED.

In some embodiments, the light-emitting component is fabricated using a sheet-to-sheet process or a roll-to-roll process.

According to one aspect of this disclosure, there is provided a method for fabricating a metasurface layer on a base layer: the method comprises: preparing a mold, the mold comprising extrusions in a predefined pattern: treating the mold by a low surface energy material to reduce surface tension and adhesion of the extrusions: coating a layer of soft and ultraviolet (UV) curable photoresist material onto the base layer: applying the mold to the layer of photoresist material for transferring the predefined pattern thereto: curing and hardening the layer of photoresist material using a UV light; and removing the mold from the hardened layer of photoresist material.

In some embodiments, said coating the layer of soft and UV curable photoresist material onto the base layer comprises: depositing the photoresist material from a dispensing unit onto the base layer; and using a blade to uniformly spread the photoresist material onto the substrate to a predefined thickness.

In some embodiments, the mold is on a first roller; and said applying the mold to the layer of photoresist material comprises rolling the first roller over the base layer to apply the mold to the layer of photoresist material for transferring the predefined pattern thereto.

In some embodiments, the first roller comprises a transparent surface; and the UV light is within the first roller.

In some embodiments, the base layer is rolled on a second roller; and the method further comprises rolling the second roller to move the base layer towards the first roller.

In some embodiments, said rolling the second roller to move the base layer towards the first roller comprises: rolling the second roller to release the base layer therefrom; and rolling one or more third rollers to move the released base layer towards the first roller.

In some embodiments, the base layer is a hybrid Ag NWs/CNTs-coated flexible substrate, or a flexible substrate coated with any other suitable material as a replacement to ITO.

### BRIEF DESCRIPTION OF THE DRAWINGS

The embodiments of the present disclosure will now be described with reference to the following figures, in which identical reference numerals in different figures indicate identical elements, and in which:

FIG. 1 is a schematic diagram illustrating the structure of a prior-art QLED or OLED device;

FIG. 2 is a schematic diagram illustrating the structure of a prior-art QLED or OLED device having an inverted structure compared to that shown in FIG. 1;

FIG. 3 is a schematic diagram illustrating the structure of a prior-art QLED device with an emissive layer (EML) comprising multiple quantum-dot (QD) and quantum-barrier (QB) sublayers:

FIG. 4 is a schematic diagram illustrating the optical losses that occur in a prior-art bottom-emitting QLED or OLED device:

FIG. 5 is a schematic diagram illustrating a prior-art conventional array of three-dimensional spherical lenses used for light extraction from OLEDs and QLEDs:

FIG. 6 is a schematic diagram illustrating a prior-art two-dimensional metasurface:

FIG. 7 is a schematic diagram illustrating a prior-art roll-to-roll processing setup:

FIG. 8 is a schematic diagram illustrating a simplified structure of an integrated optoelectronic device according to some embodiments of this disclosure:

FIG. 9 is a schematic diagram of the light extraction mechanism using integrated metalenses of the integrated optoelectronic device shown in FIG. 8, according to some embodiments of this disclosure:

FIG. 10 is a schematic diagram of the light extraction mechanism using integrated metalenses of the integrated optoelectronic device shown in FIG. 8, according to some other embodiments of this disclosure:

FIG. 11 is a schematic diagram of the light extraction mechanism using integrated metalenses of the integrated optoelectronic device shown in FIG. 8, according to yet some other embodiments of this disclosure:

FIG. 12 is a schematic diagram of the light extraction mechanism using a prior-art LED device:

FIG. 13 is a schematic diagram of the light extraction mechanism using integrated metalenses of the integrated optoelectronic device shown in FIG. 8, according to some embodiments of this disclosure:

FIGS. 14A to 14C are schematic diagrams illustrating the emission profile in a prior-art LED panel:

FIGS. 15A to 15C are schematic diagrams of the modified emission profile of the integrated optoelectronic device shown in FIG. 8, according to some embodiments of this disclosure:

FIGS. 16A to 16E are schematic diagrams of optical energy distribution profile of the integrated optoelectronic device shown in FIG. 8, according to various embodiments of this disclosure:

FIG. 17 is a schematic diagram illustrating the viewing angle of a prior-art display:

FIG. 18 is a schematic diagram of the viewing angle of the integrated optoelectronic device shown in FIG. 8, according to some embodiments of this disclosure;

FIG. 19 is a schematic diagram of the integrated optoelectronic device shown in FIG. 8, according to some other embodiments of this disclosure:

FIG. 20 is a schematic diagram of the integrated optoelectronic device shown in FIG. 8, according to yet some other embodiments of this disclosure:

FIG. 21 is a schematic diagram of the integrated optoelectronic device shown in FIG. 8 having a passive-matrix display, according to still some other embodiments of this disclosure:

FIG. 22 is a schematic diagram illustrating the structure of the passive-matrix display shown in FIG. 21:

FIG. 23 is a schematic diagram illustrating the structure of an active-matrix display, according to some embodiments of this disclosure:

FIG. 24A is a schematic diagram illustrating a mold used in a sheet-to-sheet fabrication process of metasurfaces, according to some embodiments of this disclosure:

FIG. 24B is a schematic diagram illustrating a substrate used in the sheet-to-sheet fabrication process of metasurfaces, the substrate coated with a photoresist layer:

FIG. 24C is a schematic diagram showing the mold engaging the photoresist layer of the substrate in the sheet-to-sheet fabrication process of metasurfaces:

FIG. 24D is a schematic diagram showing the substrate after the mold is removed therefrom:

FIG. 25 is a schematic diagram of a roll-to-sheet process for fabricating metasurfaces, according to some embodiments of this disclosure:

FIG. 26 is a schematic diagram of a roll-to-roll process for fabricating metasurfaces, according to some embodiments of this disclosure:

FIG. 27 is a schematic diagram of a flexible QLED panel, according to some embodiments of this disclosure:

FIG. 28 is a schematic diagram illustrating a roll-to-roll process for fabricating the integrated optoelectronic device shown in FIG. 8, according to some embodiments of this disclosure; and

FIG. 29 is a schematic diagram of a flexible passive-matrix QLED display, according to some embodiments of this disclosure.

### DETAILED DESCRIPTION

Embodiments of this disclosure relate to integrated hybrid optoelectronic devices and systems.

### A. INTEGRATED OPTOELECTRONIC DEVICE

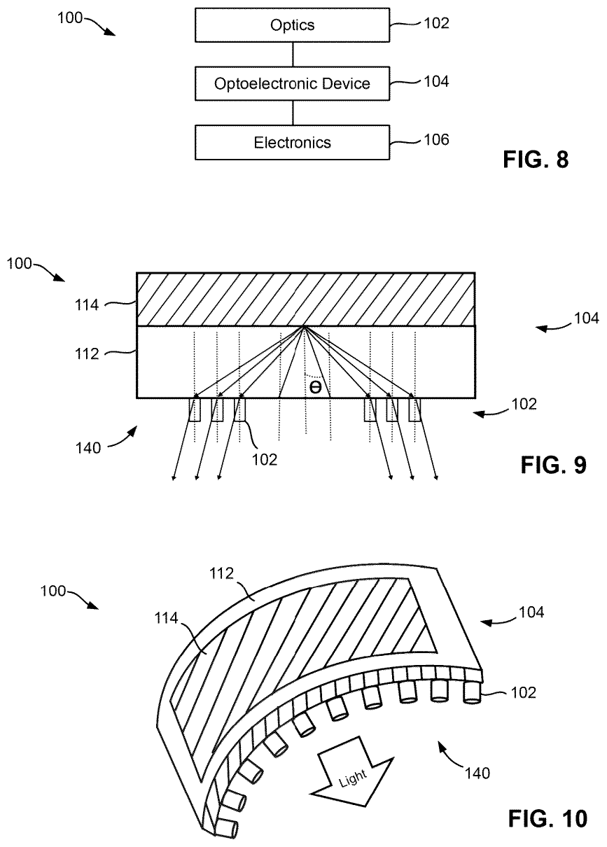

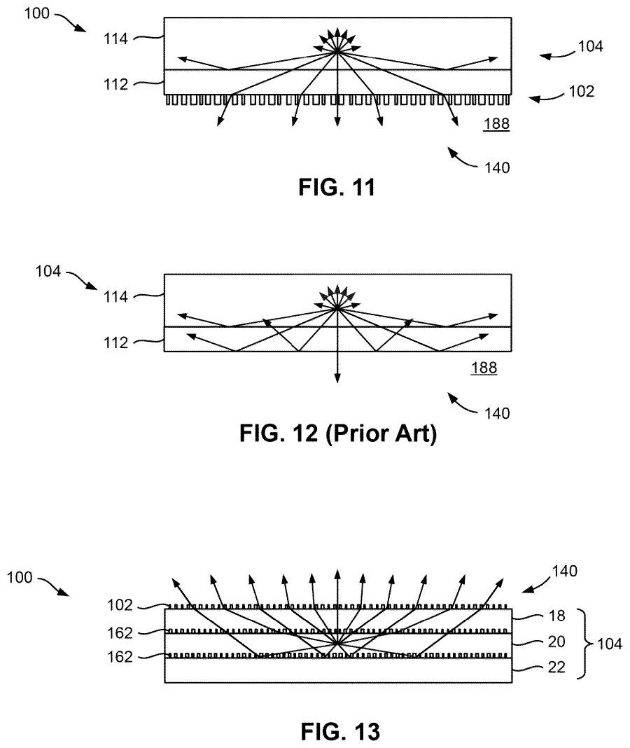

Turning now to FIG. 8, an integrated optoelectronic device according to some embodiments of this disclosure is shown and is generally identified using reference numeral 100. As shown, the optoelectronic device 100 is an integrated device comprising an optics layer 102, an optoelectronic component layer 104, and an electronics layer 106 coupled or otherwise integrated together. Such an integration provides several advantages such as high performance, high power density, better manufacturing, high repeatability, and/or the like. Moreover, the integration of various layers provides great opportunity to facilitate high-volume manufacturing through sheet-to-sheet and roll-to-roll printing of the entire device 100.

While in above embodiments, the optoelectronic device 100 comprises one optics layer 102, one optoelectronic component layer 104, and one electronics layer 106, in some embodiments, the optoelectronic device 100 may comprise a plurality of optics layers 102, a plurality of optoelectronic component layers 104, and/or a plurality of electronics layers 106. The optics layers 102, optoelectronic component layers 104, and/or electronics layers 106 may be alternately stacked with each other to form an integrated structure of the optoelectronic device 100 (described in more detail later).

In some embodiments, the optoelectronic device 100 may comprise integrated optics layers 102 and optoelectronic component layers 104, and separate electronics 106 which are physically separated from but electrically connected to the optics layers 102 and/or optoelectronic component layers 104.

### B. LIGHT EXTRACTION FROM THE OPTOELECTRONIC DEVICE

In some embodiments, the optics layer 102 may comprise a layer of metasurfaces for (1) efficient light extraction from small-area and large-area electroluminescent components such as light-emitting diodes (LEDs), organic light-emitting diodes (OLEDs), and quantum-dot light-emitting diodes (QLEDs), (2) precise engineering of light distribution in illumination systems, and/or 3) realization of ultra-directional displays and screens.

A metasurface is an ultrathin optical component comprising a two-dimensional (2D) array of nano-scale metalenses typically fabricated from high-index materials. Metalenses allow control over basic properties of light such as its phase, amplitude, and polarization (see References [42] to [44]). Therefore, metalenses may enhance the outcoupling efficiency of QLEDs and OLEDs and may manipulate the outcoupled emission profile to suit various applications in display and lighting technologies. For instance, in some applications, the emitted light from the device needs to be tilted, converged, diverged, or any combination of these.

Moreover, being practically two-dimensional ultrathin components, metasurfaces are highly compatible with planar devices such as LEDs, OLEDs, QLEDs, and photovoltaic cells, and can be readily integrated into such planar devices.

FIG. 9 shows an optoelectronic device 100 in some embodiments. For ease of illustration. FIG. 9 only shows the optics layer 102 and the optoelectronic component layer 104, and the electronics layer 106 is omitted.

In these embodiments, the optoelectronic component layer 104 is a small-area, bottom-emitting OLED or QLED 114 fabricated on an ITO-coated glass substrate 112. The OLED or QLED 114 may be any suitable OLED (with an organic emitter as the EML 20) or QLED (with one or more quantum-dot (QD) sublayers as the EML 20). For example, in one embodiment, the OLED or QLED 114 may be a conventional OLED or QLED 10 as shown in FIG. 1 wherein the substrate 112 in FIG. 9 corresponds the substrate 12 in FIG. 1 and the block 114 corresponds to other layers 14 to 24 in FIG. 1. More specifically, the optoelectronic component layer 104 in this example may be a QLED 10 comprising a single colloidal core/shell QD layer as the EML 20. The HIL 16 may be an organic material such as PEDOT:PSS, an inorganic p-type material such as copper (I) thiocyanate (CuSCN), or a p-type metal oxide (e.g. NiOₓ, MoO₃, or the like). The HTL/EBL 18 may be PVK, poly-TPD. TFB, or any other suitable hole-transporting material. The HTL/EBL 18 may also consist of a TFB/PVK or poly-TPD/PVK double-layer to provide a more effective step-wise hole injection.

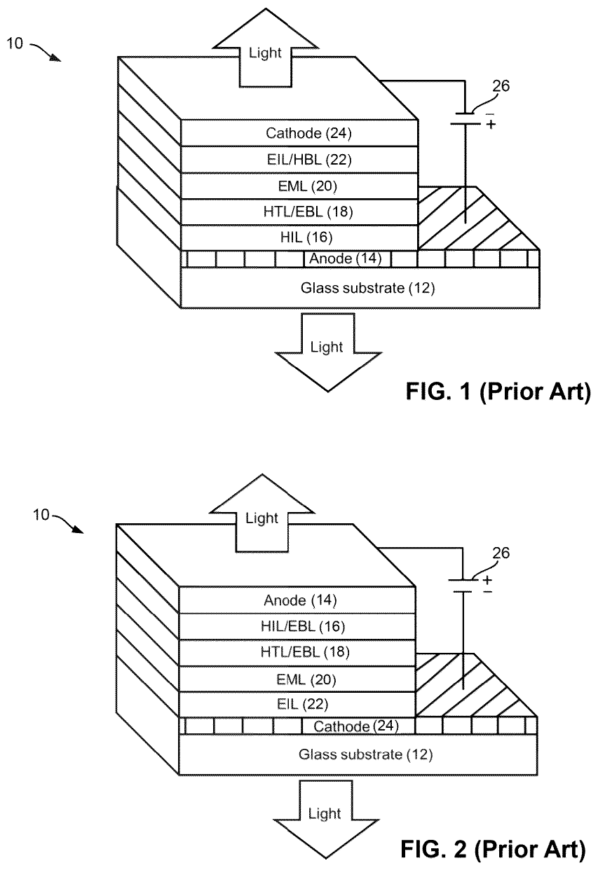

In another example, the OLED or QLED 114 may be the OLED or QLED 10 shown in FIG. 2 having an inverted structure compared to that shown in FIG. 1.

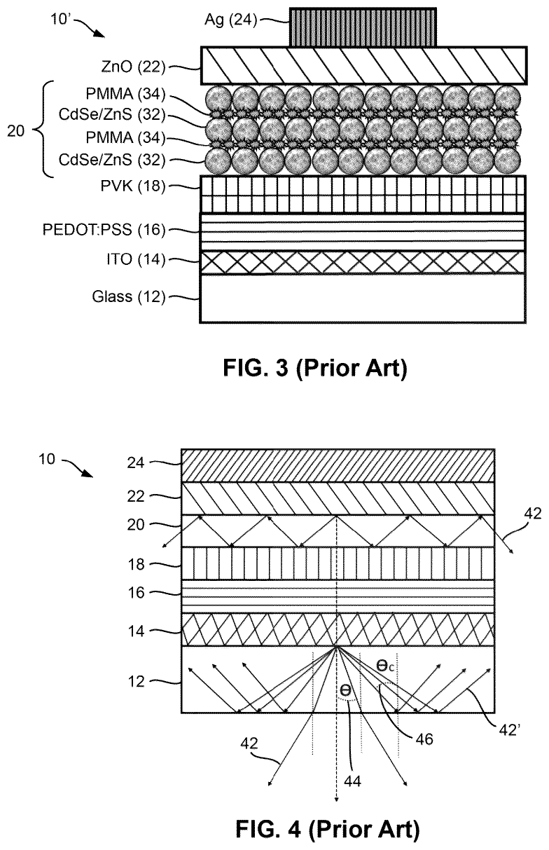

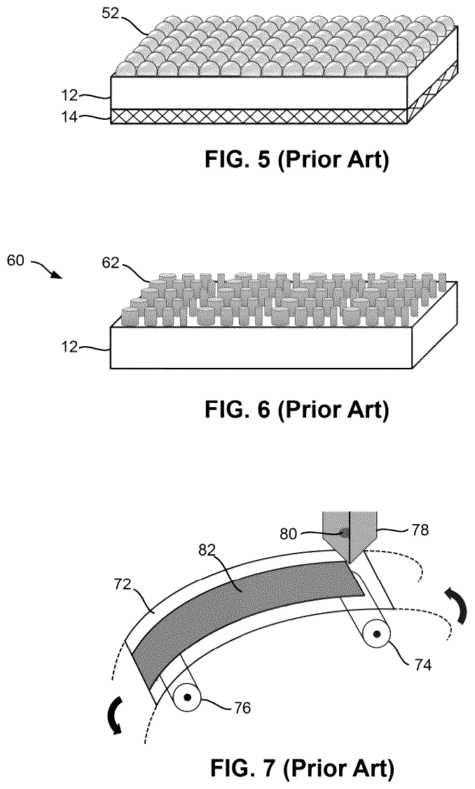

In yet another example, the OLED or QLED 114 may be the QLED 10′ shown in FIG. 3 and disclosed in Applicant's WO 2019/071362 A1 wherein the substrate 112 in FIG. 9 corresponds the substrate 12 in FIG. 3 and the block 114 corresponds to other layers 14 to 24 in FIG. 3. More specifically, the EML 20 comprises a stack of different colloidal core/shell QD sublayers 32 and quantum-barrier (QB) sublayers 34. The HIL 16 may be an organic material such as PEDOT:PSS, an inorganic p-type material such as CuSCN, or a p-type metal oxide (e.g. NiOₓ, MoO₃, or the like). The HTL/EBL 18 may be PVK, poly-TPD, TFB, or any other suitable hole-transporting material. The HTL/EBL 18 may also consist of a TFB/PVK or poly-TPD/PVK double-layer to provide a more effective step-wise hole injection.

The optics layer 102 comprises one or more metasurface units each comprising an array of nanopillar-shaped, high-index metalenses fabricated on the backside of the glass substrate 112 (or more generally, on the light-emission side 140 of the glass substrate 112). Hereinafter, the metasurface and metalenses are also identified using reference numeral 102.

The metalenses 102 are used for simultaneous enhancement of the light outcoupling efficiency and manipulating the emission profile for desired applications. The spin coating and slot-die coating techniques may be used for fabricating the various layers of the optoelectronic device 100. For example, a plastic substrate, such as a plastic substrate coated with a hybrid of silver nanowires (Ag NWs) and carbon nanotubes (hybrid Ag NWs/CNTs) (described in more detail later), may be stretched to be flattened for printing. As another example, a flexible thin glass, such as a flexible thin glass substrate coated with hybrid Ag NWs/CNTs (described in more detail later), may be used for slot-die printing.

FIG. 10 shows an optoelectronic device 100 in some embodiments. For ease of illustration, FIG. 10 only shows the optics layer 102 and the optoelectronic component layer 104, and the electronics layer 106 is omitted.

In these embodiments, the optoelectronic component layer 104 is a bottom-emitting OLED or QLED 114 which may be any suitable OLED or QLED such as the conventional OLED or QLED 10 shown in FIG. 1 or 2, the QLED 10′ shown in FIG. 3 and disclosed in Applicant's WO 2019/071362 A1, or the like (all except the glass substrate 12 shown therein). The OLED or QLED 114 is fabricated on a suitable conductive/transparent flexible substrate 112 such as a flexible substrate 112 coated with ITO, a hybrid of silver nanowires (Ag NWs) and carbon nanotubes (hybrid Ag NWs/CNTs), or the like.

The optics layer 102 comprises metalenses fabricated on the light-emission side 140 of the substrate 112. Sheet-to-sheet, sheet-to-roll, and roll-to-roll processes may be used for the fabrication of both the optoelectronic component layer 104 and the metalens layer 102.

The incorporation of the metalens layer 102 at the interface between the substrate 112 of the optoelectronic-components layer 104 and air 188 may significantly mitigate light reflections that may otherwise occur at this interface (see FIG. 12). In addition, the metasurface layer 102 may control the direction of light emitted therefrom such that the emitted light may be tilted, converged, and/or diverged as needed to suit various applications (described in more detail later).

In some embodiments, one or more metasurface layers 102 may be sandwiched between various neighboring layers of a LED device of any type in order to effectively extract the waveguide modes. The design flexibility of metasurfaces enables design of optical components with various responses. For example, in the optoelectronic device 100 shown in FIG. 13, a first metasurface layer 162 is sandwiched between the HTL/EBL layer 18 and the EML layer 20 for reducing photon reflection at the interface between the HTL/EBL layer 18 and the EML layer 20 and/or controlling the direction of light emitted from the EML layer 20. A second, reflective metasurface layer 164 is sandwiched between the EML layer 20 and the EIL/HBL layer 22 for bouncing back (that is, reflecting) the photons that propagate rearwardly (that is, away from the light-emission side 140) and otherwise would not reach the light-emission side 140. Other layers of the optoelectronic device 100 are not shown for ease of illustration.

Therefore, the use of metasurface layers between various layers inside the optoelectronic device 100 may eliminate light coupling into the waveguide modes that cannot escape the device structure, yielding an ultra-efficient optoelectronic device 100.

### C. PRECISE ENGINEERING OF LIGHT DISTRIBUTION IN ILLUMINATION SYSTEMS

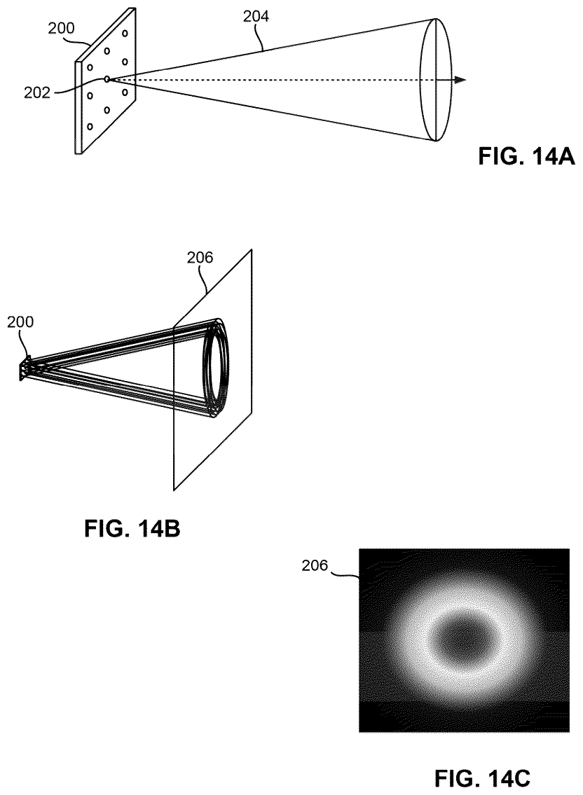

As shown in FIG. 14A, light 204 emitted from a light-emitting component 202 of a conventional lighting device 200 such as a LED panel generally propagates along the direction perpendicular to the light-emitting plane. Therefore, as shown in FIGS. 14B and 14C, the light emitted from the conventional light-emitting device 200 with a plurality of light-emitting components 202 does not project a uniform distribution on a target plane 206. Rather, the light intensity of the lighting device 200 is usually strongest at the center and gradually diminishes away from the center. Such a lighting device 200, when being used for indoor plant growth, would not provide sufficient lighting to all areas thereby causing poor growth for plants in the periphery lighting areas of the lighting device 200.

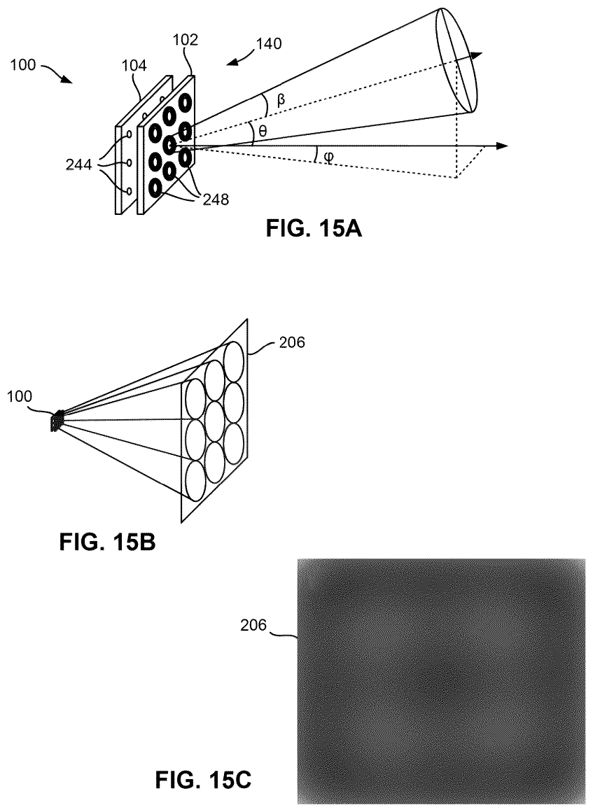

FIG. 15A shows an optoelectronic device 100 in some embodiments. As shown, the optoelectronic device 100 comprises a light-emitting layer 104 having a plurality of LED 244 and a Topocentric Vector Control Panel (TVCP) layer as the optics layer 102 overlaid to the light-emitting layer 104 on the light-emitting side 140 thereof. The TVCP layer 102 comprises metasurface units 248 at locations corresponding to those of the LED 244. The mestasurface units 248 precisely modify the angular coordinates of illumination associated with each individual LED 244 including azimuth (φ) altitude (θ), and divergence angle (β). The TVCP layer 246 thus effectively breaks the symmetry of the light distribution otherwise presents in the target plane 206 (see FIG. 14C) and achieves a uniform light distribution on the target plane 206, as shown in FIGS. 15B and 15C. This technique is powerful in that a small change in the angles can make a significant difference in the intensity distribution in the target plane.

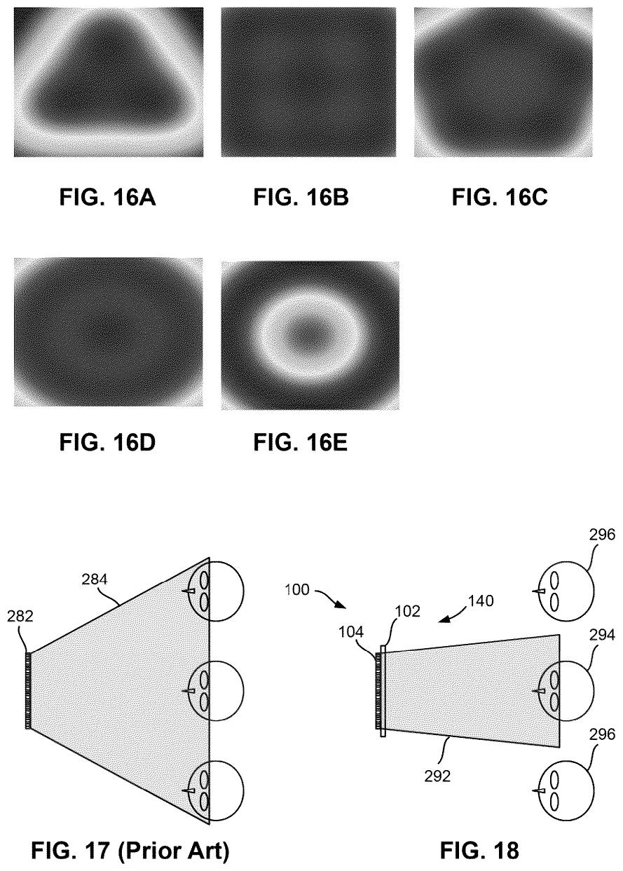

By using the TVCP layer 246, any arbitrary light-intensity distribution may be obtained. In some embodiments, machine-learning algorithms may be used to calculate the angular coordinates required to achieve a given light pattern or illumination pattern in the target plane 206. In some embodiments, the light is emitted from a plurality of pixels, and the normalized mean square error (NMSE) is used as the cost function to be minimized where

$$NMSE = \frac{\sqrt{\frac{{\sum }_{i = 1}^{N} {( I ( {x}_{i} ) - μ )}^{2}}{N}}}{{\sum }_{j = 1}^{N} I ( {x}_{j} )} \qquad ( 1 )$$

where μ is the mean value, I(xᵢ) is the intensity for the pixel i, and N is the total number of pixels in the image plane. In some embodiments, gradient descent (GD) and simulated annealing (SA) techniques may be used to find the global minimum of NMSE. More particular, the optimization starts with an initial random state given input data (such as the number of LEDs, the shape and size of the desired illumination pattern, the distance between the optoelectronic device 100 and the target plane 206, and the learning rate). The gradient of the current state is calculated, and the state is translated in the opposite direction of the gradient value multiplied by the learning rate. The optimization repeats until the maximum number of iterations (which may be user defined) is reached. Some examples of the illumination patterns generated by this method are shown in FIGS. 16A to 16E.

### D. REALIZATION OF ULTRA-DIRECTIONAL DISPLAYS AND SCREENS

In some applications, a display or screen may be only intended for a single person or limited number of people. For instance, a display in a vehicle or on an airplane is watched only by an individual. However, as shown in FIG. 17, a conventional display 282 usually has a wide viewing angle 284 sending the screen light also to people around that individual, resulting in lower brightness and the waste of optical energy for unintended purposes. Another example is the displays used in homes or theatres that inevitably light up the peripheral areas such as walls and ceiling in addition to audiences, leading to lower brightness and inefficient use of light energy.

Moreover, applications with security requirements generally require highly directional displays. For example, displays used in ATMs or in banks are highly desired to be private and exclusive for only the intended operators for protecting sensitive information such as bank account numbers and passwords. In prior art, privacy overlays with narrowed viewing angles may be applied to conventional displays with large viewing angles to limit the viewing angles thereof. However, such privacy overlays increase the cost of the displays.

FIG. 18 shows an optoelectronic device 100 in some embodiments. As shown, the optoelectronic device 100 comprises a light-emitting layer 104 having a plurality of LED 244 and a metasurface layer as the optics layer 102 overlaid to the light-emitting layer 104 on the light-emitting side 140 thereof. As the metasurface layer 102 comprises an array of nanoscale structures that allow bending light in any desired direction, the metasurface layer 102 may use this property of the nanoscale structures to form a reduced viewing angle 292 to only allow the viewer 294 at the intended direction to view the content display on the optoelectronic device 100 and prevent other viewers 296 from viewing the displayed content, thereby creating a virtual visual barrier.

This optoelectronic device 100 in these embodiments has advantages such as:
superior brightness due to the distribution of light energy into a smaller area,
power-efficient operation due to uniform distribution of light energy restricted only to the intended area, and
secure operation where visual information can be received only by the intended audience.

Metasurfaces may be designed to interact differently with light of different polarization states. This is accomplished when the nanostructures of the metasurface have an asymmetric geometry. This property may be utilized to enhance depth perception for three-dimensional visualization.

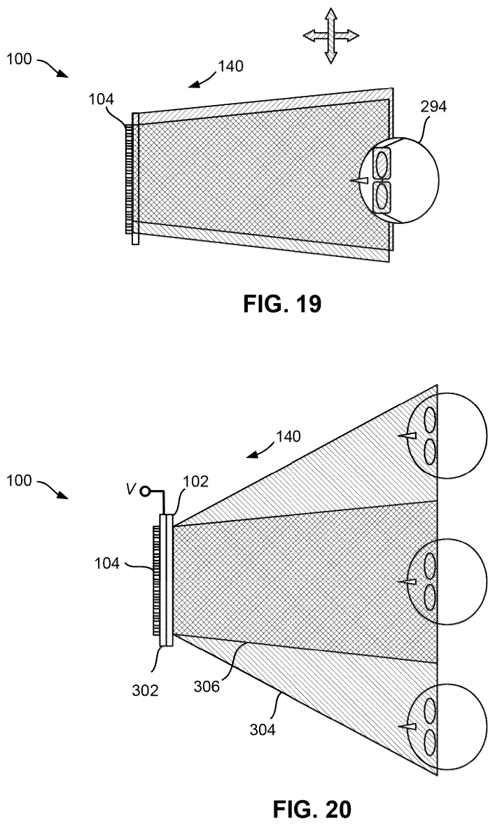

For example, in some embodiments as shown in FIG. 19, the optoelectronic device 100 comprises a light-emitting layer 104 with a plurality of LEDs each corresponding to a display pixel, and a polarization-sensitive metasurface layer as the optics layer 102 overlaid to the light-emitting layer 104 on the light-emitting side 140 thereof. The light-emitting layer 104 simultaneously displaying a left-eye image and a right-eye image via pixels at alternately positions. The polarization-sensitive metasurface layer 102 comprises a plurality of first metasurface units at positions corresponding to those of the pixels display the left-eye image (denoted “left-eye pixels”) and a plurality of second metasurface units at positions corresponding to those of the pixels display the right-eye image (denoted “right-eye pixels”). The first metasurface units polarize the light beams from left-eye pixels to a first polarization state and the second metasurface units polarize the light beams from right-eye pixels to a second polarization state orthogonal to the first polarization state. A user 294 may use a pair of glasses having lenses with suitable polarizing filters to watch the display and obtain a three-dimensional (3D) perception.

In some embodiments as shown in FIG. 20, the optoelectronic device 100 comprises a light-emitting layer 104, a polarization control layer 302 overlaid to the light-emitting layer 104 on the light-emitting side 140 thereof, and a polarization-sensitive metasurface layer as the optics layer 102 overlaid to the polarization control layer 302 on the light-emitting side 140 thereof.

The polarization control layer 302 may be implemented using liquid crystal polarization rotators which, by applying an adjustable voltage, may change the polarization state of the impinging light from the light-emitting layer 104 between either one of the two orthogonal polarization states. The polarization-sensitive metasurface layer 102 comprises metasurfaces that directs the light at the first polarization state to a wide viewing angle 304 and directs the light at the second polarization state to a narrow viewing angle 306, thereby creating a switchable field of view (FOV) between the wide and narrow viewing angles. Such an optoelectronic device 100 may be used when a user would like to temporarily create a virtual visual barrier on one occasion and share the display with others on other occasions.

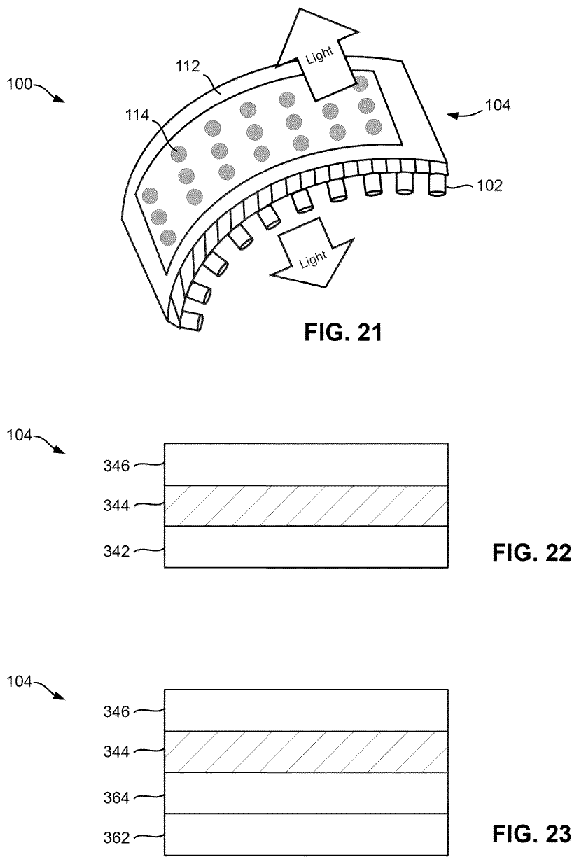

In some embodiments, the light-emitting layer 104 of the optoelectronic device 100 shown in FIG. 20 may be a conventional or an inverted, bottom-emitting, top-emitting, or a fully-transparent passive matrix OLED or QLED with the structure shown in FIG. 21, fabricated on a pre-patterned plastic substrate 112 using sheet-to-sheet or roll-to-roll printing. The polarization control layer 302 and polarization-sensitive metasurface layer 102 may be fabricated on the backside of the substrate 112 and/or on the top thereof (that is, on the opposite side or the same side of the light-emitting layer 104), depending on desired light-emitting direction(s). The polarization-sensitive metasurface layer 102 may be directly printed on the substrate 112 employing the nanoimprint lithography technique (described in more detail later).

As described above, the light-emitting layer 104 of the optoelectronic device 100 shown in FIG. 20 may be a passive matrix OLED or QLED. As shown in FIG. 22, the passive matrix OLED or QLED 104 in some embodiments may comprise a pixel-driving circuitry 342 printed onto a side of the highly conductive/transparent substrate 112 (not shown), an OLED or QLED structure 344 (such as the layers 14 to 24 shown in FIG. 1 or 2) coupled to the pixel-driving circuitry 342, and an encapsulation layer 346 coupled to the OLED or QLED structure 344, all directly printed layer-by-layer onto the pre-patterned substrate 112. In one embodiment, the substrate 112 may (preferably) be a flexible substrate coated with a highly conductive material such as a hybrid of Ag NWs and carbon nanotubes (hybrid Ag NWs/CNTs) or the like, and may be pre-patterned by conventional chemical etching methods or laser ablation [61-63]. Particularly, the use of Ag NWs/CNTs-coated plastic (for example, polyethylene terephthalate (PET), polyethylene naphthalate (poly (ethylene 2,6-naphthalate) or PEN), polycarbonates (PC), or polyimide (PI)) or flexible thin-glass substrates 112 is of significant importance for flexible displays.

In some embodiments, the light-emitting layer 104 of the optoelectronic device 100 shown in FIG. 20 may be an active-matrix OLED or QLED with the structure similar to that shown in FIG. 21 fabricated on a plastic or thin glass substrate 112 using ink-jet printing technique.

As shown in FIG. 23, the active-matrix OLED or QLED 104 in some embodiments may comprise a pixel-driving thin-film-transistor (TFT) layer 362 printed onto the entire area of the substrate 112 (not shown), a highly conductive and pre-patterned electrode 364, an OLED or a QLED structure 344 (such as the layers 14 to 24 shown in FIG. 1 or 2) printed with the ink-jet technique on the conductive electrode 364, and an encapsulation layer 346 coupled to the OLED or QLED structure 344.

### E. NANOIMPRINT LITHOGRAPHY FOR FABRICATION OF METALENSES

Due to the small scale of the nanostructures (tens of nanometers), metasurfaces cannot be fabricated using conventional ultraviolet (UV) lithography techniques. Electron-beam lithography is currently a popular technique to fabricate metasurfaces in the research settings. However, electron-beam lithography is slow and costly, thereby limiting the applications of metasurfaces only to research purposes. Widespread application of metasurfaces entails fast, cost-effective, and reliable fabrication technique that can translate this technology into the large display and illumination/energy device market.

In some embodiments, a sheet-to-sheet nanoimprint lithography technology (see Reference [64]) may be used for mass production of metasurfaces for large-area optoelectronic devices including LED panels, OLEDs, and QLEDs. The nanoimprint lithography technology disclosed below is readily integrable, fast, cost-effective, and reliable, and is suitable for mass-production of metasurfaces. Thus, the nanoimprint lithography technology disclosed below may significantly reduce the fabrication time that ultimately leads to more cost-effective and higher-yield metasurface production.

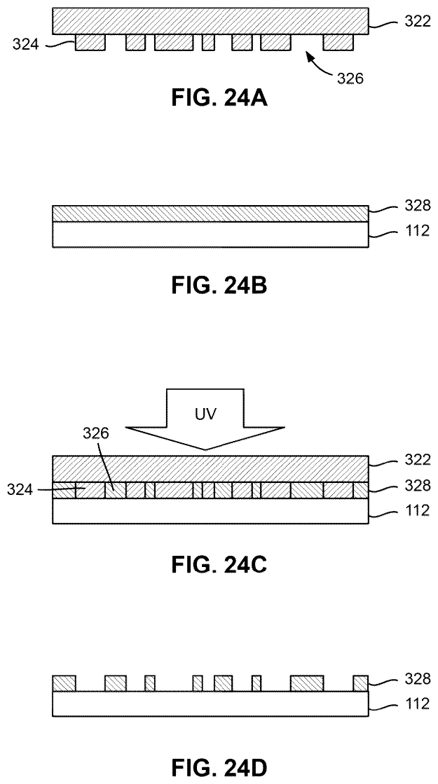

As shown in FIG. 24A, a metasurface mold 322 is fabricated, for example, by using a standard technique such as electron-beam lithography. The mold 322 comprises extrusions in a predefined pattern 324 and is treated by a low surface energy material to reduce surface tension and adhesion of the extrusions. The extrusions then form nanoscale recesses or valleys therebetween in a pattern 326 complementary to the predefined pattern 324. As will be described below; the pattern 326 (or more specifically the nanoscale recesses thereof) will form the pattern of the metasurface nanostructures after fabrication.

The mold 322 may be used for producing a large number of metasurfaces using nanoimprint lithography. As shown in FIG. 24B, the substrate 112 (which may be glass or plastic) is coated with a photoresist layer 328 that is soft and UV curable to smoothly cover the substrate 112. In these embodiments, the photoresist layer 328 may comprise a positive or negative photoresist material such as SU-8 which is an epoxy-based negative photoresist that becomes very hard after UV exposure.

As shown in FIG. 24C, the mold 322 is engaged with the photoresist layer 328 and substrate 112 such that the pattern 324 (or more specifically, the extrusions thereof) extends into the photoresist layer 328. The photoresist material of the photoresist layer 328 at the extrusions 324 of the mold 322 is repelled and that in the recesses 326 of the mold 322 is maintained.

The coupled mold 322, photoresist layer 328, and substrate 112 are then exposed under a suitable UV light to harden the photoresist layer 328. The hardened photoresist material of the photoresist layer 328 in the recesses 326 of the mold 322 then forms the metasurface nanostructures. As shown in FIG. 24D, after the photoresist layer 328 is hardened, the mold 322 is released without damaging the nanostructures.

In some embodiments, the hardened nanostructures may be coated with a suitable material for further improving the hardness thereof. Moreover, deposition and/or etching may be used for fabricating the nanostructures.

Although in above embodiments, the metasurface is fabricated on the substrate 112, in some other embodiments, the metasurface may be fabricated on other layers (denoted base layers of the metasurface) using the mold and process shown in FIGS. 24A to 24D.

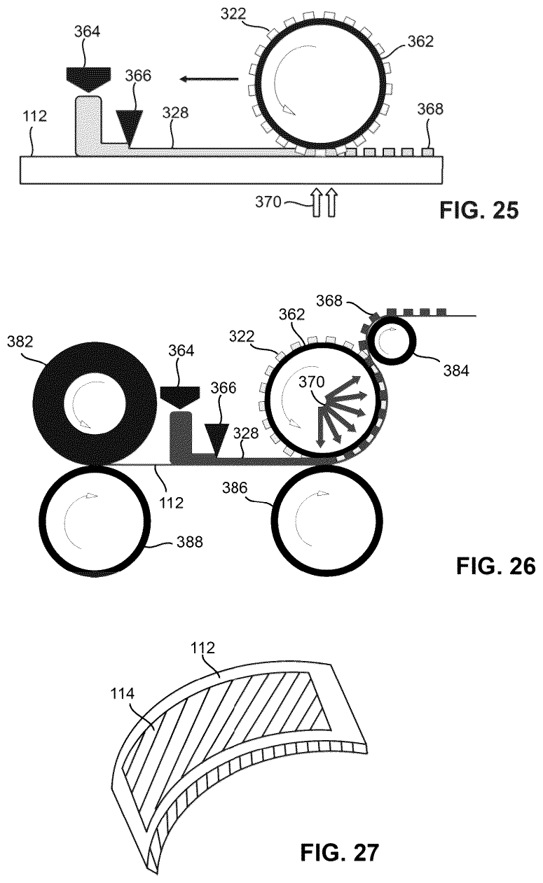

In some embodiments, nanoimprint lithography may also be accomplished using a roll-to-plate configuration. As shown in FIG. 25, the mold 322 is fabricated on a cylindrical roller (or stamping roller) 362. The imprinting is conducted by rolling the cylindrical roller 362 (and thus rolling the mold 322) over the substrate 112 coated with a photoresist 328. The photoresist material 328 is deposited from the dispensing unit 364 followed by the doctor blade 366 to uniformly spread the photoresist 328 onto the substrate 112 to the desired thickness. The photoresist-deposited substrate 112 is fixed and the stamping roller 362 is rolled over the substrate 112 to emboss the metasurface (array of metalenses) 368 on the substrate 112. This setup 20) also contains an external UV-LED light source 370) to cure the photoresist 328.

FIG. 26 shows the nanoimprint lithography technology in another embodiment using a roll-to-roll configuration. As shown, the mold 322 is fabricated on a cylindrical roller (or stamping roller) 362. The substrate 112, which is rolled on the substrate roller 382, is moved towards the fixed stamping roller 362. The photoresist material 328 is deposited from the dispensing unit 364 followed by the doctor blade 366 to uniformly spread the photoresist 328 onto the substrate 112 to the desired thickness. The photoresist-deposited substrate 112 is passed through the stamping roller 362 to emboss the metasurface (array of metalenses) 368 on the substrate 112. The stamping roller 362 has a transparent surface and contains an internal UV-LED light source 370) to cure the photoresist 328 before it is disengaged to the supporting roller 384. Two other supporting rollers 386 and 388 are also used in this embodiment. This embodiment may significantly reduce the fabrication time that ultimately leads to a more cost-effective and high-yield metasurface production.

### F. QLED DEVICES FABRICATED BY ROLL-TO-ROLL PROCESSING

In addition to integrating the above-mentioned metasurfaces for enhancing the efficiency and emission profiles of LED systems, in some embodiments, a roll-to-roll process may be used for industry-scale manufacturing of large-area flexible QLED panels and QLED passive-matrix displays on highly conductive flexible substrates.

As mentioned above, these devices may be readily integrated with the nanoimprinted metasurfaces. Furthermore, in some embodiments described below, the ITO-coated substrate is replaced with another conductive flexible substrate which, as one of the most important technical factors, provide improved efficiency and lifetime of the flexible devices (including QLEDs).

In some embodiments, highly efficient and stable colloidal Cd-based and Cd-free core/shell QDs are synthesized and incorporated into the flexible devices. By tuning the size of the synthesized QDs, one may easily tune the emission wavelength from UV to near-infrared (NIR), which enables using these QDs not only in lighting and display applications but also in, for example, medical and biological systems.

Preferably, Cd-based (for example, CdSe/ZnS, ZnCdSe/ZnSe/ZnS, and/or the like) and Cd-free (for example, InP/ZnS, InP/ZnSe/ZnS, and/or the like) colloidal core/shell and core/shell/shell QDs with a variety of sizes (and emission wavelengths from UV to NIR) may be incorporated into the flexible devices. Extremely efficient and stable devices have been recently reported with core/shell/shell QD structures (see References [46] and [65]).

In some embodiments as shown in FIG. 27, the substrate 112 may be a flexible substrate coated with hybrid Ag NWs/CNTs (see References [56] to [59]) or other suitable material. Compared to ITO-coated substrates, the hybrid Ag NWs/CNTs-coated flexible substrate 112 has high electrical conductivity, high optical transparency, superior air/moisture stability, and possibility for easy and inexpensive patterning.

In some embodiments, the substrate may also contain a barrier film for further protection against air and moisture.

In some embodiments, the flexible substrate 112, such as the hybrid Ag NWs/CNTs-coated flexible substrate 112, may also be printed as one of the early steps of the entire fabrication process.

In some embodiments, the OLED or QLED 114 may be fabricated on the flexible substrate 112 using roll-to-roll manufacturing. The OLED or QLED 114 may be any suitable OLED or QLED such as the conventional OLED or QLED 10 shown in FIG. 1 or 2, or the like (except the glass substrate 12 shown in FIG. 1 or 2).

In some embodiments, core/shell/shell QDs such as ZnCdSe/ZnSe/ZnS are used as the emitters (that is, the EML 20 shown in FIGS. 1 and 2) for their high photoluminescence quantum yields and stability.

In some embodiments, the OLED or QLED 114 may be the QLED 10′ shown in FIG. 3 and disclosed in Applicant's WO 2019/071362 A1 (except the glass substrate 12 shown in FIG. 3).

In some embodiments, an encapsulation layer is also printed as the top layer for protecting the layer thereunder.

In some embodiments, at least a portion of the electronics layer 106 may also be printed onto the substrate 112.

In some embodiments, all the layers may be printed in the roll-to-roll process.

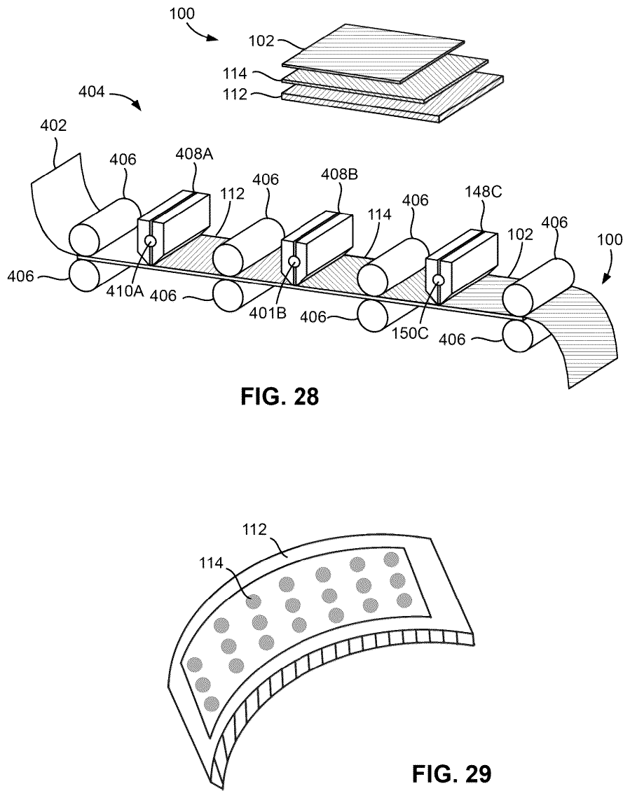

FIG. 28 illustrates an exemplary, high-volume roll-to-roll printing process for manufacturing the optoelectronic device 100. As shown, a conveyor belt 402 is forwarded through a fabrication line 404 via a plurality of roller pairs 406. While the conveyor belt 402 is moving forward, a first slot die head 408A with ink 410A prints the flexible substrate 112 onto the conveyor belt 402.

Then, a plurality of slot die heads with suitable inks (represented by the second slot die head 408B with ink 410B in FIG. 28) sequentially print the layers of the OLED or QLED 114 onto the substrate 112. By careful controlling the printing speed, printing temperature, and fluid flow rate, one may adjust the thicknesses of the charge transporting and QD layers to obtain devices with superior efficiencies even without integrating any additional light extraction systems.

After printing the layers of the OLED or QLED 114, another slot die head 408C with ink 410C may be used to print the optics layer 102 (such as the metasurface) onto the OLED or QLED 114. The optoelectronic 100 is then formed.

As described above, in some embodiments, a further slot die head with an ink of an encapsulation material may be used to print the encapsulation layer onto the optics layer 102.

In some embodiments as illustrated in FIG. 29, a sheet-to-sheet or roll-to-roll process may be used for large-scale manufacturing of passive-matrix QLED displays 114 on flexible substrates 112. Unlike active-matrix displays, these displays do not require any TFT backplane for controlling each individual pixel. The required circuitry may be easily printed on the edges of the substrate 112. The substrate 112 may be patterned with conventional chemical etching methods or laser ablation. After patterning, all the materials are printed sequentially on top of each other.

### G. REFERENCES

[1] Y. Shirasaki, G. J. Supran, M. G. Bawendi, and V. Bulovic, “Emergence of colloidal quantum-dot light-emitting technologies”, Nat. Photon. 7, 13-23 (2013).
[2] C. R. Kagan, E. Lifshitz, E. H. Sargent, and D. V. Talapin, “Building devices from colloidal quantum-dots”, Science 353, aac5523 (2016).
[3] Y. Sun, Y. Jiang, X. W. Sun, S. Zhang, and S. Chen, “Beyond OLED: Efficient quantum dot light-emitting diodes for display and lighting applications”, Chem. Rec. 19, 1-25 (2019).
[4] X. Dai, Y. Deng, X. Peng, and Y. Jin, “Quantum-dot light-emitting diodes for large-area displays: Towards the dawn of commercialization”, Adv. Mater. 29, 1607022 (2017).
[5] D. Zhang, T. Huang, and L. Duan, “Emerging self-emissive technologies for flexible displays”, Adv. Mater., 1902391 (2019).
[6] A. Salehi, X. Fu, D.-H. Shin, and F. So, “Recent Advances in OLED Optical Design”, Adv. Funct. Mater 29, 1808803 (2019).
[7] A. Shahalizad, S. Ahmadi-Kandjani, H. Movla, H. Omidi, B. Massoumi, M. S. Zakerhamidi, and A. A. Entezami, “Green-Yellow Electroluminescence from a host-dopant blended system as the active layer in a bilayer polymer light emitting diode: Poly (n-vinyl carbazole) as the host and a new soluble thiophene based copolymer [poly (2,2′-BT)-co-(3-DDT)] as the dopant”, Opt. Mater. 37, 760 (2014).
[8] F. Zhao and D. Ma, “Approaches to high performance white organic light-emitting diodes for general lighting”, Mater. Chem. Front. 1, 1933 (2017).
[9] M. Cibian, A. Shahalizad, F. Souissi, J. Castro, J. G Ferreira, D. Chartrand, J.-M. Nunzi, and G. S Hanan, “A Zinc (II) Benzamidinate N-Oxide Complex as an Aggregation-Induced Emission Material: toward Solution-Processable White Organic Light-Emitting Devices”, Eur. J. Inorg. Chem. 2018, 4322 (2018).
[10] H. Zhu, E.-S. Shin, A. Liu, D. Ji, Y. Xu, and Y.-Y. Noh, “Printable Semiconductors for Backplane TFTs of Flexible OLED Displays”, Adv. Funct. Mater., 1904588 (2019).
[11] J. H. Koo, D. C. Kim, H. J. Shim, T.-H. Kim, and D.-H. Kim, “Flexible and Stretchable Smart Display: Materials, Fabrication, Device Design, and System Integration”, Adv. Funct. Mater. 28, 1801834 (2018).
[12] Y.-F. Liu, J. Feng, Y.-G. Bi, D. Yin, and H.-B. Sun, “Recent Developments in Flexible Organic Light-Emitting Devices”, Adv. Mater. Technol. 4, 1800371 (2019).
[13] H.-W. Chen, J.-H. Lee, B.-Y. Lin, S. Chen, and S.-T. Wu, “Liquid crystal display and organic light-emitting diode display: present status and future perspectives”, Light: Science & Applications 7, 17168 (2018).
[14] M. K. Choi, J. Yang, T. Hyeon, and D.-H. Kim, “Flexible quantum dot light-emitting diodes for next-generation displays”, npj Flex. Electron. 2, 10 (2018).
[15] J. Kim, H. J. Shim, J. Yang, M. K. Choi, D. C. Kim, J. Kim, T. Hyeon, and D.-H. Kim, “Ultrathin Quantum Dot Display Integrated with Wearable Electronics”, Adv. Mater. 1700217 (2017).
[16] Y. Liu, C. Jiang, C. Song, J. Wang, L. Mu, Z. He, Z. Zhong, Y. Cun, C. Mai, J. Wang, J. Peng, and Y. Cao, “Highly Efficient All-Solution Processed Inverted Quantum Dots Based Light Emitting Diodes”, ACS Nano 12, 1564 (2018).
[17] F. Liang. Y. Liu, Y. Hu, Y.-L. Shi, Y.-Q. Liu, Z.-K. Wang, X.-D. Wang, B.-Q. Sun, and L.-S. Liao, “Polymer as an Additive in the Emitting Layer for High-Performance Quantum Dot Light-Emitting Diodes”, ACS Appl. Mater. Interfaces 9, 20239 (2017).
[18] L. Wang. T. Chen, Q. Lin, H. Shen, A. Wang, H. Wang, C. Li, L. S. Li, “High-performance azure blue quantum dot light-emitting diodes via doping PVK in emitting layer”, Org. Electron. 37, 280 (2016).
[19] H.-T. Vua, C.-Y. Huangc, H.-C. Yud, Y.-K. Su, “Ultrathin PVK charge control layer for advanced manipulation of efficient giant CdSe a, ZnS/ZnS quantum dot light-emitting diodes”, Org. Electron. 63, 349 (2018).
[20] Z. Zhang, Y. Ye, C. Pu, Y. Deng. X. Dai, X. Chen, D. Chen, X. Zheng, Y. Gao, W. Fang. X. Peng, and Y. Jin, “High-Performance, Solution-Processed, and Insulating-Layer-Free Light-Emitting Diodes Based on Colloidal Quantum Dots”, Adv. Mater. 30, 1801387 (2018).
[21] Y.-H. Won, O. Cho, T. Kim, D.-Y. Chung, T. Kim, H. Chung, H. Jang, J. Lee, D. Kim, and E. Jang. “Highly efficient and stable InP/ZnSe/ZnS quantum dot light-emitting diodes”, Nature 575, 634 (2019).
[22] H. Zhang, N. Hu, Z. Zeng, Q. Lin, F. Zhang, A. Tang, Y. Jia, L. S. Li, H. Shen, F. Teng, and Z. Du, “High-Efficiency Green InP Quantum Dot-Based Electroluminescent Device Comprising Thick-Shell Quantum Dots”, Adv. Optical Mater. 7, 1801602 (2019).
[23] J. Lim, M. Park, W. K. Bae, D. Lee, S. Lee, C. Lee, and K. Char, “Highly Efficient Cadmium-Free Quantum Dot Light-Emitting Diodes Enabled by the Direct Formation of Excitons within InP@ZnSeS Quantum Dots”, ACS Nano 7, 9019 (2013).
[24] M. T. Clarke, F. N. Viscomi, T. W. Chamberlain, N. Hondow, A. M. Adawi, J. Sturge, S. C. Erwin, J.-S. G. Bouillard, S. Tamang, and G. J. Stasiuk, Commun. Chem. 2:36 (2019).
[25] F. Guo, A. Karl, Q.-F. Xue, K. C. Tam, K. Forberich, and C. J. Brabec, “The fabrication of color-tunable organic light-emitting diode displays via solution processing”, Light: Science & Applications 6, 17094 (2017).
[26] B. R. Lee, E. D. Jung, J. S. Park, Y. S. Nam, S. H. Min, B.-S. Kim, K.-M. Lee, J.-R. Jeong, R. H. Friend, J.-S. Kim, S. O. Kim, and M. H. Song, “Highly efficient inverted polymer light-emitting diodes using surface modifications of ZnO layer”, Nat. Commun. 5:4840 (2014).
[27] Y. He, N. Cheng, X. Xu, J. Fu, J.-an Wang, “A high efficiency pure organic room temperature phosphorescence polymer PPV derivative for OLED”, Org. Electron. 64, 247 (2019).
[28] M. Mergani, A. Shahalizad, S. Ahmadi-Kandjani, M. S. Zakerhamidi, Phys. Scr. T157 (2013).
[29] H. Uoyama, K. Goushi, K. Shizu, H. Nomura, and C. Adachi, “Highly efficient organic light-emitting diodes from delayed fluorescence”, Nature 492, 234 (2012).
[30] C. Adachi, M. A. Baldo, M. E. Thompson, and S. R. Forrest, “Nearly 100% internal phosphorescence efficiency in an organic light-emitting device”, J. Appl. Phys. 90, 5048 (2001).
[31] H. Nakanotani, T. Higuchi, T. Furukawa, K. Masui, K. Morimoto, M. Numata, H. Tanaka, Y. Sagara, T. Yasuda, C. Adachi, “High-efficiency organic light-emitting diodes with fluorescent emitters”, Nat. Commun. 5, 4016 (2014).
[32] S. Nowy, B. C. Krummacher, J. Frischeisen, N. A. Reinke, and W. Brütting, “Light extraction and optical loss mechanisms in organic light-emitting diodes: Influence of the emitter quantum efficiency”, J. Appl. Phys. 104, 123109 (2008).
[33] R. Meerheim, M. Furno, S. Hofmann, B. Lüssem, and K. Leo, “Quantification of energy loss mechanisms in organic light-emitting diodes”, Appl. Phys. Lett. 97, 253305 (2010).
[34] C. Fuchs, P.-A. Will, M. Wieczorek, M. C. Gather, S. Hofmann, S. Reineke, K. Leo, and R. Scholz, “Enhanced light emission from top-emitting organic light-emitting diodes by optimizing surface plasmon polariton losses”, Phys. Rev. B 92, 245306 (2015).
[35] K. Xu, C. Lu, Y. Huang, J. Hu, and X. Wang, “Enhanced outcoupling efficiency and removal of the microcavity effect in top-emitting OLED by using a simple vapor treated corrugated film”, RSC Adv.7, 54876 (2017).
[36] M. J. Park, G. H. Kim, Y. H. Son, H. W. Bae, J. H. Kong, and J. H. Kwon, “High efficiency red top-emitting micro-cavity organic light emitting diodes”, Opt. Exp. 22, 19919 (2014).
[37] Y.-G. Bi, J. Feng, Y.-S. Liu, Y.-F. Li, Y. Chen, X.-L. Zhang, X.-C. Han, H.-B. Sun, “Surface Plasmon-Polariton Mediated Red Emission from Organic Light-Emitting Devices Based on Metallic Electrodes Integrated with Dual-Periodic Corrugation”, Sci. Rep. 4, No. 7108 (2015).
[38] T.-B. Lim, K. H. Cho, Y.-H. Kim, and Y.-C. Jeong, “Enhanced light extraction efficiency of OLEDs with quasiperiodic diffraction grating layer”, Opt. Exp. 24, 17950 (2016).
[39] S. Wedge, I. R. Hooper, I. Sage, and W. L. Barnes, “Light emission through a corrugated metal film: The role of cross-coupled surface plasmon polaritons”, Phys. Rev. B 69, 245418 (2004).
[40] J. P. Yang, Q. Y. Bao, Z. Q. Xu, Y. Q. Li, J. X. Tang, and S. Shen, “Light out-coupling enhancement of organic light-emitting devices with microlens array”, Appl. Phys. Lett. 97, 223303 (2010).
[41] F. Galeotti, W. Mróz, G. Scavia, C. Botta, “Microlens arrays for light extraction enhancement in organic light-emitting diodes: A facile approach”, Org. Electron. 14, 212 (2013).
[42] M. Khorasaninejad and F. Capasso, “Metalenses: Versatile multifunctional photonic components”, Science 358, eaam8100 (2017).
[43] H. Pahlevaninezhad, M. Khorasaninejad, Y.-W. Huang, Z. Shi, L. P. Hariri, D. C. Adams, V. Ding, A. Zhu, C.-W. Qiu, F. Capasso, and M. J Suter, Nat. Photon. 12, 540 (2018).
[44] M. L. Tseng, H.-H. Hsiao, C. H. Chu, M. K. Chen, G. Sun, A.-Q. Liu, and D. P. Tsai, “Metalenses: Advances and Applications”, Adv. Optical Mater. 6, 1800554 (2018).
[45] M. Rahmati, S. dayneko, M. Pahlevani, and Y. Shi, “Highly Efficient Quantum Dot Light-Emitting Diodes by Inserting Multiple Poly (methyl methacrylate) as Electron-Blocking Layers”, Adv. Funct. Mater. 29, 1906742 (2019).
[46] J. Song, O. Wang, H. Shen, Q. Lin, Z. Li, L. Wang, X. Zhang, and L. S. Li, “Over 30% External Quantum Efficiency Light-Emitting Diodes by Engineering Quantum Dot-Assisted Energy Level Match for Hole Transport Layer”, Adv. Funct. Mater. 29, 1808377 (2019).
[47] X. Li, Y.-B. Zhao, F. Fan, L. Levina, M. Liu, R. Q.-Bermudez, X. Gong, L. N. Quan, J. Z. Fan, Z. Yang, S. Hoogland, O. Voznyy, Z.-H. Lu, and E. H. Sargent, “Bright colloidal quantum dot light-emitting diodes enabled by efficient chlorination”, Nat. Photon. 12, 159 (2018).
[48] H. Shen, Q. Gao, Y. Zhang, Y. Lin, Q. Lin, Z. Li, L. Chen, Z. Zeng, X. Li, Y. Jia, S. Wang, Z. Du, L. S Li, and Z. Zhang, “Visible quantum dot light-emitting diodes with simultaneous high brightness and efficiency”, Nat. Photon. 13, 192 (2019).
[49] X. Dai, Z. Zhang, Y. Jin, Y. Niu, H. Cao, X. Liang, L. Chen, J. Wang, and X. Peng, “Solution-processed, high-performance light-emitting diodes based on quantum dots”, Nature 515, 96 (2014).
[50] P. Yang, L. Zhang, D. J. Kang, R. Strahl, and T. Kraus, “High-Resolution Inkjet Printing of Quantum Dot Light-Emitting Microdiode Arrays”, Adv. Optical Mater. 8, 1901429 (2020).
[51] C. Jiang, Z. Zhong, B. Liu, Z He, J. Zou, L. Wang, J. Wang, J. B. Peng, and Y. Cao, “Coffee-Ring-Free Quantum Dot Thin Film Using Inkjet Printing from a Mixed-Solvent System on Modified ZnO Transport Layer for Light-Emitting Devices”, ACS Appl. Mater. Interfaces 8, 26162 (2016).
[52] G. Azzellino, F. S. Freyria, M. Nasilowski, M. G. Bawendi, and V. Bulović, “Micron-Scale patterning of High Quantum Yield quantum Dot LEDs”, Adv. Mater. Technol. 4, 1800727 (2019).
[53] T. Tsujimura, J. Fukawa, K. Endoh, Y. Suzuki, K. Hirabayashi, T. Mori, “Development of flexible organic light-emitting diode on barrier film and roll-to-roll manufacturing”, J. SID 22, 412 (2014).
[54] R. R. Sondergaard, M. Hösel, and F. C. Krebs, “Roll-to-Roll Fabrication of Large Area Functional Organic Materials”, J. Polym. Sci., Part B 51, 16 (2013).
[55] B.-O. Choi, B.-S. Ryu, K.-J. Lim, K.-Y. Kim, D.-S. Kim, S.-N. Yun, Y.-B. Ham, T.-M. Lee, J.-D. Jo, H.-E. Lim, and C.-S. Yoo, “Method and apparatus for manufacturing electronic device using roll-to-roll rotary pressing process”, U.S. Pat. No. 8,689,687 B2, Apr. 8, 2014.
[56] K. Shin, J. Park, and C. Lee, “A 250-mm-width, flexible, and continuous roll-to-roll slot-die coated carbon nanotube/silver nanowire film fabrication and a study on the effect of anti-reflective overcoat”, Thin Solid Films 598, 95 (2016).
[57] B.-Y. Wang, E.-S. Lee, D.-S. Lim, H. W. Kang, and Y.-J. Oh, “Roll-to-roll slot die production of 300 mm large area silver nanowire mesh films for flexible transparent electrodes”, RSC Adv. 7, 7540 (2017).
[58] D.-J. Kim, H.-I. Shin, E.-H. Ko, K.-H. Kim, T.-W. Kim, and H.-K. Kim, “Roll-to-roll slot-die coating of 400 mm wide, flexible, transparent Ag nanowire films for flexible touch screen panels”, Sci. Rep. 6, No. 34322 (2016).
[59] C.-L. Kim, C.-W. Jung, Y.-J. Oh, and D.-E. Kim, “A highly flexible transparent conductive electrode based on nanomaterials”, npj Asia Materials 9, e438 (2017).
[60] J. Park, K. Shin, and C. Lee, “Roll-to-Roll Coating Technology and Its Applications: A Review”, Int. J. Precis. Eng. Manuf. 17, 537 (2016).
[61] W. li, A. Meredov, and A. Shamim, “Coat-and-print patterning of silver nanowires for flexible and transparent electronics”, npj Flexible Electronics 3, No. 19, (2019).
[62] G.-S. Liu, C. Liu, H.-J. Chen, W. Cao, J.-S. Qiu, H.-P. D. Shieh, and B.-R. Yang, “Electrically robust silver nanowire patterns transferrable onto various substrates”, Nanoscale 8, 5507 (2016).
[63] J. D. Park, S. Lim, and H. Kim, “Patterned silver nanowire using gravure printing process for flexible applications”, Thin Solid Films 586, 70 (2015).
[64] L. M. Coxa, A. M. Martinez, A. K. Blevins, N. Sowan, Y. Ding, and C. N. Bowman, “Nanoimprint lithography: Emergent materials and methods of actuation”, Nanotoday 31, 100838 (2020).
[65] X. Li, Q. Lin, J. Song, H. Shen, H. Zhang, L. S. Li, X. Li, and Z. Du, “Quantum-Dot Light-Emitting Diodes for Outdoor Displays with High Stability at High Brightness”, Adv. Optical Mater. 8, 1901145 (2019).

1. A light-emitting component comprising:
a plurality of photon generation and transferring layers, the photon generation and transferring layers comprising an emissive layer for generating photons and one or more photon-transferring layers coupled to the emissive layer for transferring photons from the emissive layer for emitting light; and
one or more metasurface layers, each metasurface layer comprising a two-dimensional (2D) array of nanostructures, and the one or more metasurface layers comprising one or more first metasurface layers each sandwiched between a neighboring pair of the photon generation and transferring layers for reducing photon reflection at an interface thereof.

2. The light-emitting component of claim 1, wherein the one or more photon-transferring layers comprise a plurality of photon-transferring layers on opposite sides of the emissive layer.

3. The light-emitting component of claim 1, wherein the one or more photon-transferring layers are on a first side of the emissive layer; and
wherein the one or more metasurface layers further comprise a second metasurface layer on a second side of the emissive layer opposite to the first side thereof for reflecting the photons towards the first side.

4. The light-emitting component of claim 1, wherein the one or more metasurface layers further comprise a third metasurface layer coupled to an outer side of an outmost layer of the one or more photon-transferring layers for adjusting at least one of a phase, an amplitude, and a polarization of the emitted light.

5. The light-emitting component of claim 4, wherein the array of nanostructures of the third metasurface layer are determined using a machine-learning method for forming a predefined light pattern on a target plane.

6. The light-emitting component of claim 5, wherein the machine-learning method is configured for calculating angular coordinates of the emitted light for forming the predefined light pattern on the target plane.

7. The light-emitting component of claim 6, wherein the emitted light is emitted from a plurality of pixels; and
wherein the machine-learning method is configured for using a normalized mean square error (NMSE) as a cost function to be minimized where
$$NMSE = \frac{\sqrt{\frac{{\sum }_{i = 1}^{N} {( I ( {x}_{i} ) - μ )}^{2}}{N}}}{{\sum }_{j = 1}^{N} I ( {x}_{j} )}$$
where μ is a mean value, I(xᵢ) is an intensity for pixel i, and Nis a total number of pixels in the image plane.

8. The light-emitting component of claim 7, wherein the machine-learning method is configured for using a gradient descent (GD) and simulated annealing (SA) method to find a global minimum of NMSE.

9. (canceled)

10. The light-emitting component of claim 1 further comprising:
a transparent substrate coated with transparent silver nanowires (Ag NWs) or a hybrid of Ag NWs and carbon nanotubes (hybrid Ag NWs/CNTs).

11. (canceled)

12. The light-emitting component of claim 10, wherein the substrate comprises polyethylene terephthalate (PET), polyethylene naphthalate (poly (ethylene 2,6-naphthalate) or PEN), polycarbonates (PC), polyimide (PI), or flexible thin glass.

13. The light-emitting component of claim 1, wherein the photon generation and transferring layers and the one or more metasurface layers are fabricated using spin coating or slot-die coating.

14. The light-emitting component of claim 1, wherein at least one of the one or more metasurface layers is printed on a neighboring layer thereof.

15. (canceled)

16. (canceled)

17. The light-emitting component of claim 1, wherein the light-emitting component is fabricated using a sheet-to-sheet process or a roll-to-roll process.

18. A method for fabricating a metasurface layer on a base layer, the method comprising:
preparing a mold, the mold comprising extrusions in a predefined pattern;
treating the mold by a low surface energy material to reduce surface tension and adhesion of the extrusions;
coating a layer of soft and ultraviolet (UV) curable photoresist material onto the base layer;
applying the mold to the layer of photoresist material for transferring the predefined pattern thereto;
curing and hardening the layer of photoresist material using a UV light; and
removing the mold from the hardened layer of photoresist material.

19. The method of claim 18, wherein said coating the layer of soft and UV curable photoresist material onto the base layer comprises:
depositing the photoresist material from a dispensing unit onto the base layer; and
using a blade to uniformly spread the photoresist material onto the substrate to a predefined thickness.

20. The method of claim 18, wherein the mold is on a first roller; and
wherein said applying the mold to the layer of photoresist material comprises:
rolling the first roller over the base layer to apply the mold to the layer of photoresist material for transferring the predefined pattern thereto.

21. The method of claim 20, wherein the first roller comprises a transparent surface; and
wherein the UV light is within the first roller.

22. The method of claim 18, wherein the base layer is rolled on a second roller; and the method further comprising:
rolling the second roller to move the base layer towards the first roller.

23. The method of claim 22, wherein said rolling the second roller to move the base layer towards the first roller comprises:
rolling the second roller to release the base layer therefrom; and
rolling one or more third rollers to move the released base layer towards the first roller.

24. The method of claim 18, wherein the base layer is a hybrid Ag NWs/CNTs-coated flexible substrate.
